(19) United States
(12) Patent Application Publication
(10) Pub. No.: US 2016/0223872 A1
(43) Pub. Date: Aug. 4, 2016

(54) LIQUID CRYSTAL DISPLAY DEVICE

(71) Applicant: Samsung Display Co., Ltd., Yongin-si (KR)

(72) Inventors: Woo-Seok JEON, Seoul (KR); Sung Hoon YANG, Seoul (KR); Chang Ok KIM, Yongin-si (KR); Jung Yun JO, Namyangju-si (KR)

(21) Appl. No.: 14/808,570

(22) Filed: Jul. 24, 2015

(30) Foreign Application Priority Data
Jan. 30, 2015 (KR) 10-2015-0015217

(51) Int. Cl. G02F 1/1343; G02F 1/1333; G02F 1/1368; H01L 27/12; G02F 1/1362

(52) U.S. Cl. CPC G02F 1/134309; H01L 27/124; G02F 1/136286; G02F 1/1368; G02F 1/13439; G02F 1/133345

(57) ABSTRACT

A liquid crystal display device includes a substrate; a gate line and a data line positioned on the substrate; a thin film transistor connected to the gate line and the data line; a passivation layer positioned on the gate line, the data line, and the thin film transistor; a first electrode positioned on the passivation layer; an interlayer insulating layer positioned on the first electrode; and a second electrode positioned on the interlayer insulating layer, wherein the first electrode includes a first layer made of an indium-zinc oxide in which a weight ratio of an indium oxide is 20 wt % or less or made of a transparent metal oxide that does not contain an indium oxide.

### CLAIM OF PRIORITY

This application claims the priority to and all the benefits of Korean Patent Application No. 10-2015-0015217 filed in the Korean Intellectual Property Office (KIPO) on Jan. 30, 2015, the entire contents of which are incorporated herein by reference.

### BACKGROUND OF THE INVENTION

1. Field of Disclosure

The present invention relates to a liquid crystal display device. More particularly, the present invention relates to a liquid crystal display device capable of increasing transmittance.

2. Description of the Related Art

A liquid crystal display device, which is one of the flat panel display devices that are currently used widely, includes two display panels on which electric field generating electrodes such as a pixel electrode, a common electrode, and the like, are formed, and a liquid crystal layer interposed between the two display panels, and generates an electric field in the liquid crystal layer by applying a voltage to the electric field generating electrode, thereby determining alignment of liquid crystal molecules of the liquid crystal layer and controls polarization of incident light, thereby displaying an image.

The liquid crystal display device has an advantage that thinness is easy, but has a disadvantage that side surface visibility is lower than front surface visibility. Therefore, various methods of arranging and driving a liquid crystal for overcoming this disadvantage have been developed. As a method for implementing a wide viewing angle, a liquid crystal display device in which a pixel electrode and a common electrode are formed on one substrate to form a horizontal electric field has been prominent.

In the liquid crystal display device in this horizontal electric field scheme, the pixel electrode or the common electrode are formed so as to have slit patterns having a rod shape, and an interlayer insulating layer is formed between the pixel electrode and the common electrode. Here, the pixel electrode and the common electrode may be made of a transparent metal oxide such as an indium tin oxide (ITO), an indium zinc oxide (IZO), or the like. In addition, the interlayer insulating layer may be made of a silicon oxide (SiOₓ) or a silicon nitride (SiNₓ).

When hydrogen gas (H₂) or silane SiN₄ gas is supplied in order to form the interlayer insulating layer on an electrode layer made of a transparent metal oxide such as an indium tin oxide (ITO), an indium zinc oxide (IZO), or the like, oxide of indium is reduced to be precipitated as a metal. Therefore, the electrode layer becomes opaque, such that transmittance is decreased.

The above information disclosed in this Background section is only for enhancement of understanding of the background of the invention and therefore it may contain information that does not form the prior art that is already known in this country to a person of ordinary skill in the art.

### SUMMARY OF THE INVENTION

The present invention has been made in an effort to provide a liquid crystal display device having advantages of increasing transmittance.

An exemplary embodiment of the present invention provides a liquid crystal display device including: a substrate; a gate line and a data line positioned on the substrate; a thin film transistor connected to the gate line and the data line; a passivation layer positioned on the gate line, the data line, and the thin film transistor; a first electrode positioned on the passivation layer; an interlayer insulating layer positioned on the first electrode; and a second electrode positioned on the interlayer insulating layer, wherein the first electrode includes a first layer made of an indium-zinc oxide in which a weight ratio of an indium oxide is 20 wt % or less or made of a transparent metal oxide that does not contain an indium oxide.

The first layer may be made of an aluminum zinc oxide or a gallium zinc oxide.

The interlayer insulating layer may be made of a silicon oxide or a silicon nitride.

The passivation layer may be made of an organic insulating material.

The first electrode may further include a second layer positioned under the first layer.

The first layer may be made of an aluminum zinc oxide or a gallium zinc oxide.

The second layer may be made of an indium zinc oxide or an indium tin oxide.

The first electrode may further include a third layer positioned under the second layer.

The third layer may be made of an indium-zinc oxide in which a weight ratio of an indium oxide is 20 wt % or less or be made of a transparent metal oxide that does not contain an indium oxide.

The second layer may be made of an indium zinc oxide or an indium tin oxide.

The first electrode may further include: a second layer positioned under the first layer; and a first mixed layer positioned between the first layer and the second layer.

The first layer may be made of a first material, the second layer may be made of a second material, and the first mixed layer may be made of a mixture of the first material and the second material.

In the first mixed layer, ratios of the first material and the second material may be changed in a thickness direction.

The closer to the first layer, the higher the ratio of the first material in the first mixed layer, and the closer to the second layer, the higher the ratio of the second material in the first mixed layer.

The first material may be an aluminum zinc oxide or a gallium zinc oxide.

The second material may be an indium zinc oxide or an indium tin oxide.

The first electrode may be formed by an atomic layer deposition method or a plasma enhanced atomic layer deposition method.

The first electrode may further include: a third layer positioned under the second layer; and a second mixed layer positioned between the second layer and the third layer.

The first layer and the third layer may be made of a first material, the second layer may be made of a second material, and the first mixed layer and the second mixed layer may be made of a mixture of the first material and the second material.

In the first mixed layer and the second mixed layer, ratios of the first material and the second material may be changed in a thickness direction.

The closer to the first layer, the higher the ratio of the first material in the first mixed layer, and the closer to the second layer, the higher the ratio of the second material in the first mixed layer, and the closer to the third layer, the higher the ratio of the first material in the second mixed layer, and the closer to the second layer, the higher the ratio of the second material in the second mixed layer.

The first material may be an indium-zinc oxide in which a weight ratio of an indium oxide is 20 wt % or less or be a transparent metal oxide that does not contain an indium oxide.

The second material may be an indium zinc oxide or an indium tin oxide.

The first electrode may be formed by an atomic layer deposition method or a plasma enhanced atomic layer deposition method.

a predetermined voltage may be applied to the first electrode.

The second electrode may be connected to the thin film transistor.

As described above, the liquid crystal display device according to exemplary embodiments of the present invention has the following effect.

In the liquid crystal display device according to exemplary embodiments of the present invention, a content of the indium oxide of the electrode positioned under the interlayer insulating layer is decreased to prevent reduction of oxide of indium, thereby making it possible to increase transmittance.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings, in which like reference symbols indicate the same or similar components, wherein:

FIG. 1 is a plan view of a liquid crystal display device according to an exemplary embodiment of the present invention.

FIG. 2 is a cross-sectional view of the liquid crystal display device according to an exemplary embodiment of the present invention taken along line II-II of FIG. 1.

FIG. 3 is a cross-sectional view of the liquid crystal display device according to an exemplary embodiment of the present invention.

FIG. 4 is a cross-sectional view of the liquid crystal display device according to an exemplary embodiment of the present invention.

FIG. 5 is a cross-sectional view of the liquid crystal display device according to an exemplary embodiment of the present invention.

FIG. 6 is a view showing a change in a refractive index of a first electrode in a thickness direction in the liquid crystal display device according to an exemplary embodiment of the present invention.

FIGS. 7 to 11 are process cross-sectional views showing a method of forming a first layer, a first mixed layer, and a second layer of the first electrode.

FIG. 12 is a cross-sectional view of the liquid crystal display device according to an exemplary embodiment of the present invention.

FIG. 13 is a view showing a change in a refractive index of a first electrode in a thickness direction in the liquid crystal display device according to an exemplary embodiment of the present invention.

### DETAILED DESCRIPTION OF THE INVENTION

Hereinafter, exemplary embodiments of the present invention will be described more fully with reference to the accompanying drawings so as to be easily practiced by those skilled in the art to which the present invention pertains. As those skilled in the art would realize, the described embodiments may be modified in various different ways, all without departing from the spirit or scope of the present invention.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

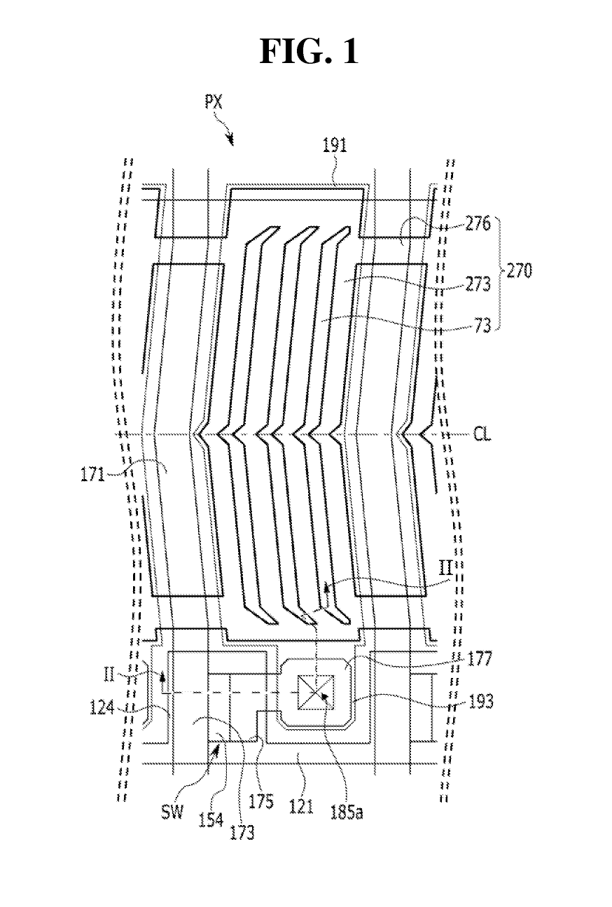

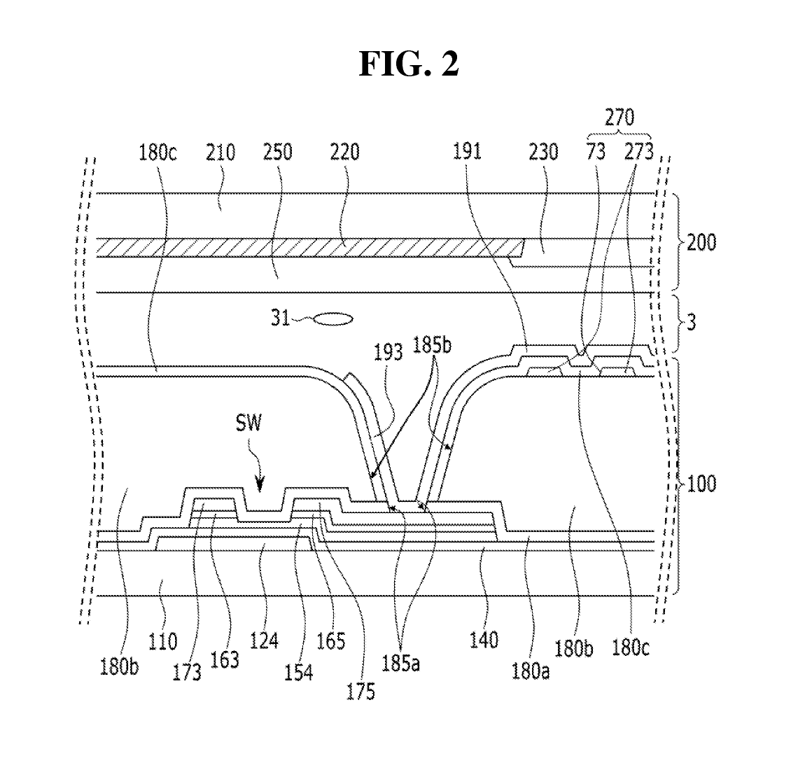

Next, a liquid crystal display device according to an exemplary embodiment of the present invention will be described with reference to FIGS. 1 to 2.

FIG. 1 is a plan view of a liquid crystal display device according to an exemplary embodiment of the present invention, and FIG. 2 is a cross-sectional view of the liquid crystal display device according to an exemplary embodiment of the present invention taken along line II-II of FIG. 1

Referring to FIGS. 1 and 2, the liquid crystal display device according to an exemplary embodiment of the present invention includes a lower display panel 100 and an upper display panel 200 facing each other, and a liquid crystal layer 3 interposed between the upper and lower display panels 100 and 200.

First, the lower display panel 100 will be described.

A gate conductor including a plurality of gate lines 121 and gate electrodes 124 protruding from the gate lines 121 is formed in one direction on a first insulation substrate 110 made of transparent glass, plastic, or the like.

The gate lines 121 are mainly extended in a horizontal direction and transfer gate signals. The gate electrodes 124 may be formed in a shape in which they protrude from the gate lines 121 as shown or be formed of portions of the gate lines 121.

Although not shown, sustain electrodes may be further formed so as not to be connected to the gate lines 121 and the gate electrodes 124. The sustain electrode may be formed in a direction that is in parallel with the gate line 121, and may have a predetermined voltage such as a common voltage, or the like, applied thereto.

A gate insulating layer 140 is formed on the gate lines 121 and the gate electrodes 124. The gate insulating layer 140 may be made of an inorganic insulating material such as a silicon nitride (SiNₓ), a silicon oxide (SiOₓ), or the like. In addition, the gate insulating layer 140 may be formed of a single layer or a multilayer.

Semiconductors 154 are formed on the gate insulating layer 140. The semiconductor 154 may be positioned above the gate electrode 124. The semiconductor 154 may be made of amorphous silicon, polycrystalline silicon, a metal oxide, or the like.

Ohmic contact members 163 and 165 may be further positioned on the semiconductors 154. Each of the ohmic contact members may be made of a material such as silicide or n+ hydrogenated amorphous silicon doped with n-type impurities at a high concentration.

Data lines 171 including source electrodes 173 and data conductors including drain electrodes 175 are positioned on the ohmic contact members 163 and 165 and the gate insulating layer 140.

The data lines 171 transfer data signals and are mainly extended in a vertical direction to intersect with the gate lines 121. The data lines 171 may be periodically bent (FIG. 1). For example, as shown in FIG. 1, the respective data lines 171 may be bent at least once at portions corresponding to a horizontal central line CL of one pixel PX.

The source electrodes 173 do not protrude from the data lines 171, but may be positioned on the same line as the data lines 171, as shown in FIG. 1. The drain electrode 175 faces the source electrode 173. The drain electrode 175 may include a rod shaped part extended substantially in parallel with the source electrode 173 and an extension part 177 disposed at an opposite side to the rod shaped part.

The gate electrode 124, the source electrode 173, and the drain electrode 175 form one thin film transistor (TFT) together with the semiconductor 154. The thin film transistor may serve as a switching element SW transferring a data voltage of the data line 171. Here, a channel of the switching element SW is formed in the semiconductor 154 between the source electrode 173 and the drain electrode 175.

A first passivation layer 180a is positioned on exposed portions of the data line 171, the source electrode 173, the drain electrode 175, and the semiconductor 154. The passivation layer 180a may be made of an inorganic insulating material such as a silicon nitride (SiNₓ), a silicon oxide (SiOₓ), or the like. The first passivation layer 180a may include a contact hole 185a exposing a part of the drain electrode 175, for example, the extension part 177.

A second passivation layer 180b may be further positioned on the first passivation layer 180b. The second passivation layer 180b may be made of an organic insulating material. The second passivation layer 180b may include an opening 185b corresponding to the contact hole 185a of the first passivation layer 180a. The opening 185b may be larger than the contact hole 185a, as shown, or substantially coincide with the contact hole 185a.

First electrodes 270 may be positioned on the second passivation layer 180b. The first electrode 270 has a predetermined voltage such as a common voltage Vcom applied thereto. The first electrodes 270 positioned in a plurality of pixels PX may be connected to each other through a connection leg 276, or the like, to transfer substantially the same common voltage Vcom. The first electrode 270 may include a plurality of branch electrodes 273. Slits 73 in which electrodes are removed are formed between neighboring branch electrodes 273.

The first electrode 270 may be formed of a single layer.

The first electrode 270 may be an indium zinc oxide (IZO). The indium zinc oxide (IZO) is made of an indium oxide (In₂O₃) and a zinc oxide (ZnO). Here, it is preferable that a weight ratio of the indium oxide is 20 wt % or less. The first electrode 270 may also be made of a transparent metal oxide that does not contain the indium oxide (In₂O₃). For example, the first electrode 270 may be made of an aluminum zinc oxide (AZO) or a gallium zinc oxide (GZO). That is, it is preferable that the first electrode 270 does not contain the indium zinc oxide or contains a small amount of indium zinc oxide.

Both of the indium zinc oxide (IZO) and the indium tin oxide (ITO) contain the indium oxide (In₂O₃). When weight ratios of the indium oxide (In₂O₃) and the zinc oxide (ZnO) in the indium zinc oxide are 90 wt % and 10 wt %, respectively, atomic weight ratios of the indium oxide (In₂O₃) and the zinc oxide (ZnO) are 73 at % and 27 at %, respectively. When weight ratios of the indium oxide (In₂O₃) and the tin oxide (SnO₂) in the indium tin oxide are 90 wt % and 10 wt %, respectively, atomic weight ratios of the indium oxide (In₂O₃) and the tin oxide (SnO₂) are 83 at % and 17 at %, respectively. That is, when weight ratios of the indium oxides in the indium zinc oxide and the indium tin oxide are the same as each other, an atomic weight ratio of the indium oxide in the indium-zinc oxide is relatively less than that of the indium oxide in the indium-tin oxide. It is more preferable that the first electrode 270 is made of the indium zinc oxide in which the atomic weight ratio of the indium oxide is less, than that the first electrode 270 is made of the indium-tin oxide.

For example, the first electrode 270 may be made of an indium-zinc oxide in which a weight ratio of the indium oxide (In₂O₃) is 20 wt % and a weight ratio of the zinc oxide (ZnO) is 80 wt %. Here, in the indium-zinc oxide, an atomic weight ratio of the indium oxide (In₂O₃) is 7 at %, and an atomic weight ratio of the zinc oxide (ZnO) is 93 at %. In addition, the first electrode 270 may be made of an indium-zinc oxide in which a weight ratio of the indium oxide (In₂O₃) is 10 wt % and a weight ratio of the zinc oxide (ZnO) is 90 wt %. Here, in the indium-zinc oxide, an atomic weight ratio of the indium oxide (In₂O₃) is 3 at %, and an atomic weight ratio of the zinc oxide (ZnO) is 97 at %.

An interlayer insulating layer 180c is formed on the first electrode 270. The interlayer insulating layer 180c may be made of an inorganic insulating material such as a silicon nitride (SiNₓ), a silicon oxide (SiOₓ), or the like.

In order to deposit the interlayer insulating layer 180c made of the silicon nitride (SiNₓ) or the silicon oxide (SiOₓ), hydrogen gas (H₂) or silane (SiH₄) gas is used. A hydrogen radical is generated from this reaction gas to allow a reduction reaction to be generated while taking away oxygen of the first electrode 270 made of the transparent metal oxide. A material in which the reduction reaction is most highly generated among transparent metal oxides is the indium oxide (In₂O₃). In an exemplary embodiment of the present invention, the first electrode 270 is made of a transparent metal oxide that contains a low content of the indium oxide (In₂O₃) or does not contain the indium oxide (In₂O₃), thereby making it possible to prevent the generation of the reduction reaction in a process of depositing the interlayer insulating layer 180c. Therefore, it is possible to prevent an indium metal from being precipitated, and transmittance is increased.

Second electrodes 191 are formed on the interlayer insulating layer 180c. The second electrodes 191 of the respective pixels PX may have a planar shape. The second electrode 191 is overlapped with the plurality of branch elements 273 of the first electrode 270. The second electrode 191 and the first electrode 270 are separated from each other by the interlayer insulating layer 180c. The interlayer insulating layer 180c serves to insulate the second electrode 191 and the first electrode 270 from each other.

The second electrode 191 may include a protrusion part 193 for connection to another layer. The protrusion part 193 of the second electrode 191 is physically and electrically connected to the drain electrode 175 through the contact hole 185a to receive a voltage applied from the drain electrode 175. The second electrode 191 may be made of a transparent metal oxide such as an indium tin oxide (ITO), an indium zinc oxide (IZO), or the like.

The second electrode 191 may include a side bent along a bent shape of the data line 171. For example, the second electrode 191 may be formed of a polygon including a side bent at least once in the portion corresponding to the horizontal central line CL of the pixel PX.

The second electrode 191 receiving the data voltage through the switching element SW and the first electrode 270 receiving the common voltage Vcom, which are two electric field generating electrodes, generate an electric field in the liquid crystal layer 3 together with each other, thereby determining a direction of liquid crystal molecules 31 of the liquid crystal layer 3 and displaying an image. Particularly, the branch electrodes 273 of the first electrode 270 form a fringe field in the liquid crystal layer 3 together with the second electrode 191, thereby making it possible to determine an alignment direction of the liquid crystal molecules 31. The liquid crystal display device according to an exemplary embodiment of the present invention may further include at least one polarizer, and be operated in a normally black mode or a normally white mode depending on a polarization axis direction of the polarizer.

According to another exemplary embodiment of the present invention, positions of the second electrode 191 and the first electrode 270 may also be exchanged with each other. That is, although the case in which the interlayer insulating layer 180c is formed on the first electrode 270 and the second electrode 191 is formed on the interlayer insulating layer 180c has been described in the present exemplary embodiment, the interlayer insulating layer 180c may be formed on the second electrode 191, and the first electrode 270 may be formed on the interlayer insulating layer 180c. In addition, the second electrode 191 may include branch electrodes and slits, and the first electrode 270 may have a planar shape.

Although not shown, a first alignment layer may be formed on an inner surface of the lower display panel 100. The first alignment layer may be positioned on the second electrode 191.

Next, the upper display panel 200 will be described.

A light blocking member 220 is formed on a second insulation substrate 210 made of transparent glass, plastic, or the like. The light blocking member 220 is also called a black matrix and prevents light leakage. The light blocking member 220 may be formed at boundary parts of pixel areas, such as the gate lines 121, the data lines 171, and the thin film transistors, and the like.

A plurality of color filters 230 are also formed on the second insulation substrate 210. The color filters 230 may be mainly present in regions enclosed by the light blocking member 220, and may be lengthily extended in the vertical direction along a column of the second electrode 191. Each of the color filters 230 may display one of primary colors such as three primary colors including a red, a green, and a blue. An example of the primary colors may include three primary colors of a red, a green, and a blue, and a yellow, a cyan, a magenta, and the like. Although not shown, the color filters may further include a color filter displaying a mixed color of the primary colors or a white in addition to the primary colors.

An overcoat 250 may be formed on the color filters 230 and the light blocking member 220. The overcoat 250 may be made of an organic insulating material, prevent the color filters 230 from being exposed, and provide a flat surface. The overcoat 250 may also be omitted.

Although not shown, a second alignment layer may be formed on an inner surface of the upper display panel 200. The second alignment layer may be positioned on the overcoat 250.

The liquid crystal layer 3 may include the liquid crystal molecules 31 having a dielectric anisotropy. The liquid crystal molecule 31 may have a positive dielectric anisotropy or a negative dielectric anisotropy. The liquid crystal molecule 31 may be arranged so that a long side thereof is in parallel with the display panels 100 and 200 in a state in which the electric field is not present in the liquid crystal layer 3. That is, the liquid crystal molecule 31 may be horizontally aligned. The liquid crystal molecule 31 may also be aligned so as to have a pre-tilt in a predetermined direction.

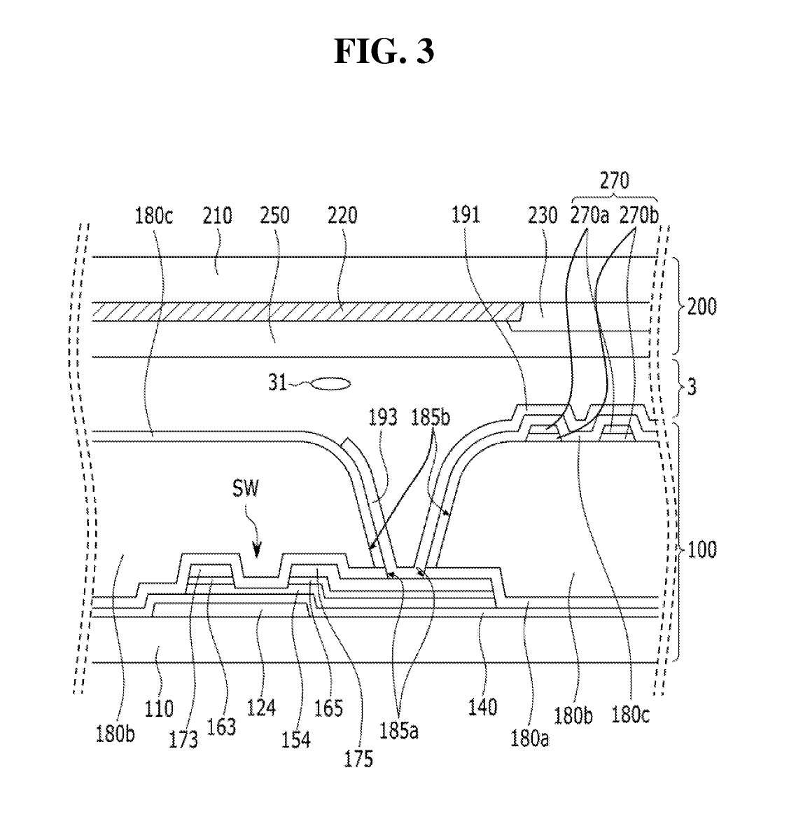

Next, the liquid crystal display device according to an exemplary embodiment of the present invention will be described with reference to FIG. 3.

Since the liquid crystal display device according to an exemplary embodiment of the present invention shown in FIG. 3 is substantially similar to the liquid crystal display device according to an exemplary embodiment of the present invention shown in FIGS. 1 and 2, a description therefor will be omitted. The liquid crystal display device according to the present exemplary embodiment is partially different from the liquid crystal display device according to the previous exemplary embodiment in that a first electrode is configured of a double layer, which will be described in detail.

FIG. 3 is a cross-sectional view of the liquid crystal display device according to an exemplary embodiment of the present invention.

Similar to the previous exemplary embodiment, the liquid crystal display device according to an exemplary embodiment of the present invention includes a lower display panel 100 and an upper display panel 200 facing each other, and a liquid crystal layer 3 interposed between the upper and lower display panels 100 and 200.

The lower display panel 100 includes gate lines 121 and data lines 171 positioned on a first insulation substrate 110 and thin film transistors connected to the gate lines 121 and the data lines 171. A first passivation layer 180a and a second passivation layer 180b are positioned on the gate lines 121, the data lines 171, and the thin film transistors. First electrodes 270 are positioned on the second passivation layer 180b, an interlayer insulating layer 180c is positioned on the first electrodes 270, and second electrodes 191 are positioned on the interlayer insulating layer 180c.

The first electrode 270 is formed of the single layer in the previous exemplary embodiment, while the first electrode 270 is formed of a double layer in the present exemplary embodiment. The first electrode 270 includes a first layer 270a and a second layer 270b positioned under the first layer 270a.

The first layer 270a of the first electrode 270 may be an indium zinc oxide (IZO). The indium zinc oxide (IZO) is made of an indium oxide (In₂O₃) and a zinc oxide (ZnO). Here, it is preferable that a weight ratio of the indium oxide is 20 wt % or less. The first layer 270a of the first electrode 270 may also be made of a transparent metal oxide that does not contain the indium oxide (In₂O₃). For example, the first layer 270a of the first electrode 270 may be made of an aluminum zinc oxide (AZO) or a gallium zinc oxide (GZO). That is, it is preferable that the first layer 270a of the first electrode 270 does not contain the indium zinc oxide or contains a small amount of indium zinc oxide.

The second layer 270b of the first electrode 270 may be made of an indium zinc oxide (IZO) or an indium tin oxide (ITO). Here, a weight ratio of an indium oxide (In₂O₃) in the indium zinc oxide (IZO) or the indium tin oxide (ITO) may be 80 wt % or more. That is, the second layer 270b of the first electrode 270 may contain a large amount of indium-zinc oxide.

The interlayer insulating layer 180c is positioned on the first electrode 270, and the first layer 270a of the first electrode 270 is exposed in a process of forming the interlayer insulating layer 180c. That is, the interlayer insulating layer 180c contacts the first layer 270a of the first electrode 270, and does not contact the second layer 270b of the first electrode 270. A reduction reaction may be generated by hydrogen gas (H₂) or silane (SiH₄) gas used in order to deposit the interlayer insulating layer 180c made of a silicon nitride (SiNₓ) or a silicon oxide (SiOₓ). In an exemplary embodiment of the present invention, the first layer 270a of the first electrode 270 exposed in the process of forming the interlayer insulating layer 180c is made of a transparent metal oxide that contains a low content of the indium oxide (In₂O₃) or does not contain the indium oxide (In₂O₃), thereby making it possible to prevent the generation of the reduction reaction in a process of depositing the interlayer insulating layer 180c.

In addition, in the present exemplary embodiment, the second layer 270b of the first electrode 270 that does not directly contact the interlayer insulating layer 180c may be made of a transparent metal oxide in which a content of the indium oxide (In₂O₃) is high. The higher the content of the indium oxide (In₂O₃), the higher the electrical conductivity. Since the second layer 270b of the first electrode 270 is not exposed in the process of forming the interlayer insulating layer 180c, the reduction reaction is not generated in the second layer 270b. Therefore, in the present exemplary embodiment, precipitation of the indium metal is prevented, thereby making it possible to increase transmittance and improve electrical conductivity of the first electrode 270.

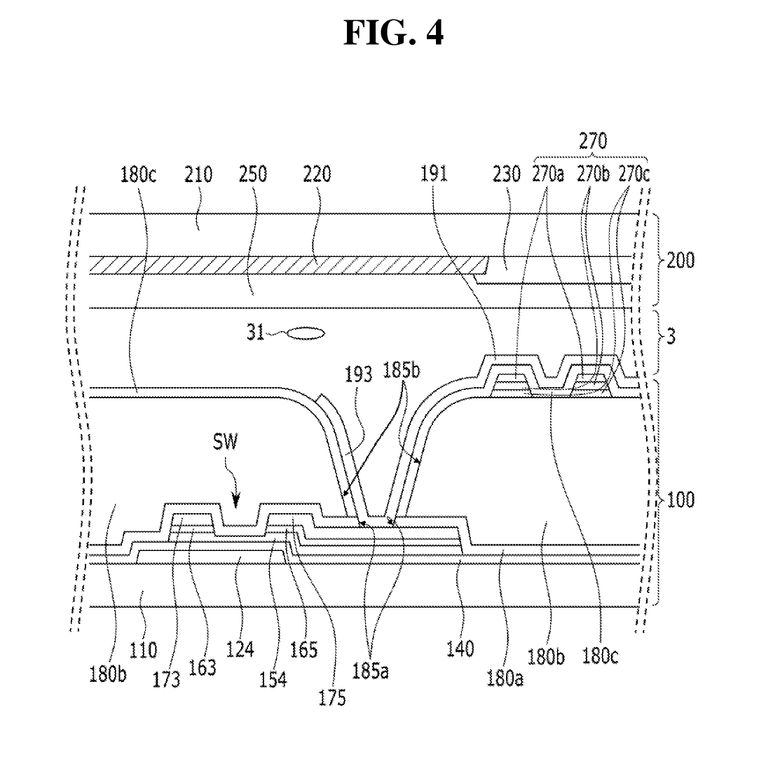

Next, the liquid crystal display device according to an exemplary embodiment of the present invention will be described with reference to FIG. 4.

Since the liquid crystal display device according to an exemplary embodiment of the present invention shown in FIG. 4 is substantially similar to the liquid crystal display device according to an exemplary embodiment of the present invention shown in FIG. 3, a description therefor will be omitted. The liquid crystal display device according to the present exemplary embodiment is partially different from the liquid crystal display device according to the previous exemplary embodiment in that a first electrode is configured of a triple layer, which will be described in detail.

FIG. 4 is a cross-sectional view of the liquid crystal display device according to an exemplary embodiment of the present invention.

Similar to the previous exemplary embodiment, the liquid crystal display device according to an exemplary embodiment of the present invention includes a lower display panel 100 and an upper display panel 200 facing each other, and a liquid crystal layer 3 interposed between the upper and lower display panels 100 and 200.

The lower display panel 100 includes gate lines 121 and data lines 171 positioned on a first insulation substrate 110 and thin film transistors connected to the gate lines 121 and the data lines 171. A first passivation layer 180a and a second passivation layer 180b are positioned on the gate lines 121, the data lines 171, and the thin film transistors. First electrodes 270 are positioned on the second passivation layer 180b, an interlayer insulating layer 180c is positioned on the first electrodes 270, and second electrodes 191 are positioned on the interlayer insulating layer 180c.

The first electrode 270 is formed of the double layer in the previous exemplary embodiment, while the first electrode 270 is formed of a triple layer in the present exemplary embodiment. The first electrode 270 includes a first layer 270a, a second layer 270b positioned under the first layer 270a, and a third layer 270c positioned under the second layer 270b.

The first layer 270a of the first electrode 270 may be an indium zinc oxide (IZO). The indium zinc oxide (IZO) is made of an indium oxide (In₂O₃) and a zinc oxide (ZnO). Here, it is preferable that a weight ratio of the indium oxide is 20 wt % or less. The first layer 270a of the first electrode 270 may also be made of a transparent metal oxide that does not contain the indium oxide (In₂O₃). For example, the first layer 270a of the first electrode 270 may be made of an aluminum zinc oxide (AZO) or a gallium zinc oxide (GZO). That is, it is preferable that the first layer 270a of the first electrode 270 does not contain the indium zinc oxide or contains a small amount of indium zinc oxide.

The second layer 270b of the first electrode 270 may be made of an indium zinc oxide (IZO) or an indium tin oxide (ITO). Here, a weight ratio of an indium oxide (In₂O₃) in the indium zinc oxide (IZO) or the indium tin oxide (ITO) may be 80 wt % or more. That is, the second layer 270b of the first electrode 270 may contain a large amount of indium-zinc oxide.

The third layer 270c of the first electrode 270 may be an indium zinc oxide (IZO). The indium zinc oxide (IZO) is made of an indium oxide (In₂O₃) and a zinc oxide (ZnO). Here, it is preferable that a weight ratio of the indium oxide is 20 wt % or less. The third layer 270c of the first electrode 270 may also be made of a transparent metal oxide that does not contain the indium oxide (In₂O₃). For example, the third layer 270c of the first electrode 270 may be made of an aluminum zinc oxide (AZO) or a gallium zinc oxide (GZO). That is, it is preferable that the third layer 270c of the first electrode 270 does not contain the indium zinc oxide or contains a small amount of indium zinc oxide.

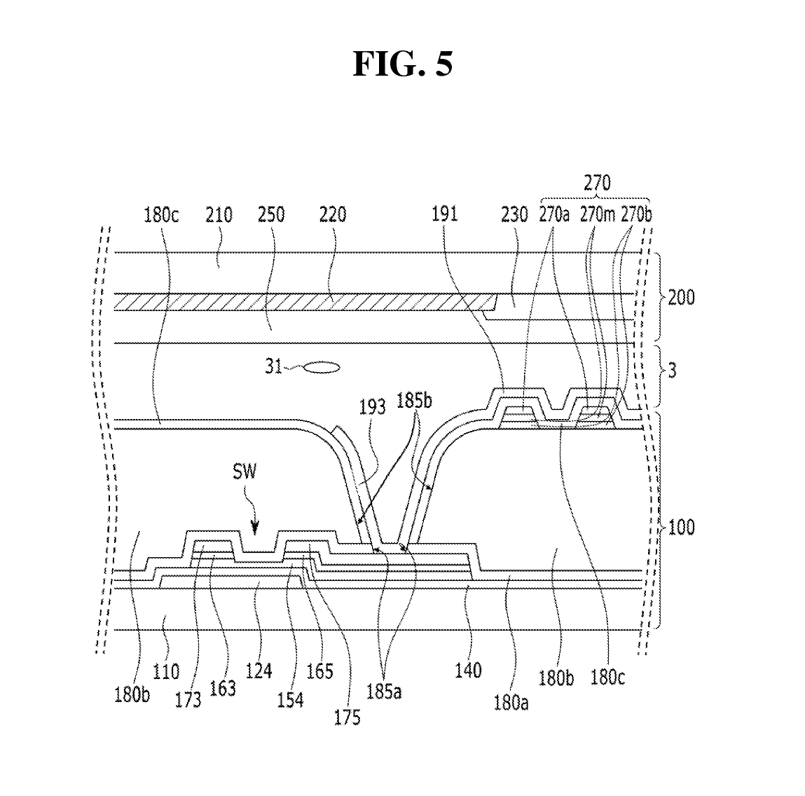

Next, the liquid crystal display device according to an exemplary embodiment of the present invention will be described with reference to FIG. 5.

Since the liquid crystal display device according to an exemplary embodiment of the present invention shown in FIG. 5 is substantially similar to the liquid crystal display device according to an exemplary embodiment of the present invention shown in FIG. 3, a description therefor will be omitted. The liquid crystal display device according to the present exemplary embodiment is partially different from the liquid crystal display device according to the previous exemplary embodiment in that a mixed layer is further positioned between first and second layers of a first electrode, which will be described in detail

FIG. 5 is a cross-sectional view of the liquid crystal display device according to an exemplary embodiment of the present invention.

Similar to the previous exemplary embodiment, the liquid crystal display device according to an exemplary embodiment of the present invention includes a lower display panel 100 and an upper display panel 200 facing each other, and a liquid crystal layer 3 interposed between the upper and lower display panels 100 and 200.

The lower display panel 100 includes gate lines 121 and data lines 171 positioned on a first insulation substrate 110 and thin film transistors connected to the gate lines 121 and the data lines 171. A first passivation layer 180a and a second passivation layer 180b are positioned on the gate lines 121, the data lines 171, and the thin film transistors. First electrodes 270 are positioned on the second passivation layer 180b, an interlayer insulating layer 180c is positioned on the first electrodes 270, and second electrodes 191 are positioned on the interlayer insulating layer 180c.

The first electrode 270 includes a first layer 270a and a second layer 270b positioned under the first layer 270a. In addition, the first electrode further includes a first mixed layer 270m positioned between the first and second layers 270a and 270b.

The first layer 270a of the first electrode 270 may be an indium zinc oxide (IZO). The indium zinc oxide (IZO) is made of an indium oxide (In₂O₃) and a zinc oxide (ZnO). Here, it is preferable that a weight ratio of the indium oxide is 20 wt % or less. The first layer 270a of the first electrode 270 may also be made of a transparent metal oxide that does not contain the indium oxide (In₂O₃). For example, the first layer 270a of the first electrode 270 may be made of an aluminum zinc oxide (AZO) or a gallium zinc oxide (GZO). That is, it is preferable that the first layer 270a of the first electrode 270 does not contain the indium zinc oxide or contains a small amount of indium zinc oxide.

The second layer 270b of the first electrode 270 may be made of an indium zinc oxide (IZO) or an indium tin oxide (ITO). Here, a weight ratio of an indium oxide (In₂O₃) in the indium zinc oxide (IZO) or the indium tin oxide (ITO) may be 80 wt % or more. That is, the second layer 270b of the first electrode 270 may contain a large amount of indium-zinc oxide.

The first mixed layer 270m of the first electrode 270 is made of a mixture of a first material configuring the first layer 270a and a second material configuring the second layer 270b. Here, ratios of the first material and the second material are changed in a thickness direction. The closer to the first layer 270a, the higher the ratio of the first material in the first mixed layer 270m, and the closer to the second layer 270b, the higher the ratio of the second material in the first mixed layer 270m. That is, a ratio of the first material is higher than that of the second material in an upper region of the first mixed layer 270m, a ratio of the second material is higher than that of the first material in a lower region of the first mixed layer 270m, and ratios of the first material and the second material are similar to each other in an intermediate region of the first mixed layer 270m.

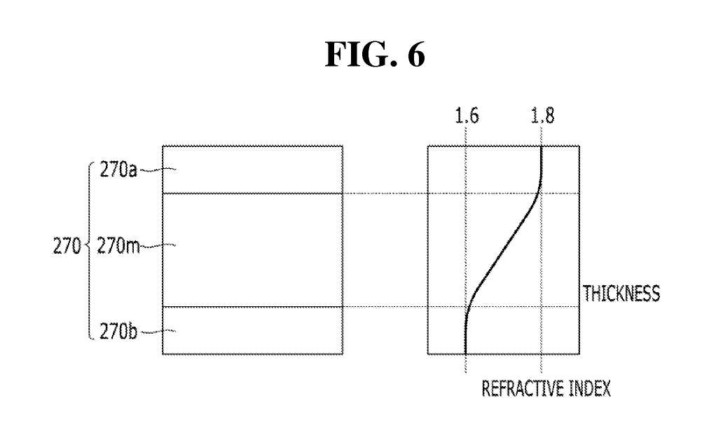

A change in a refractive index of the first electrode 270 depending on a mixed ratio of the first and second materials will be described below with reference to FIG. 6.

FIG. 6 is a view showing a change in a refractive index of a first electrode in a thickness direction in the liquid crystal display device according to an exemplary embodiment of the present invention.

The first layer 270a of the first electrode 270 may be made of the aluminum zinc oxide (AZO), and the second layer 270b thereof may be made of the indium tin oxide (ITO). Here, the first mixed layer 270m may be made of a mixture of the aluminum zinc oxide (AZO) and the indium tin oxide (ITO).

A refractive index of the first layer 270a made of the aluminum zinc oxide (AZO) is about 1.8, and a refractive index of the second layer 270b made of the indium tin oxide (ITO) is about 1.6. A refractive index of the first mixed layer 270m may be between about 1.6 and about 1.8. Since a ratio of the aluminum zinc oxide (AZO) is higher than that of the indium tin oxide (ITO) in the upper region of the first mixed layer 270m, the upper region of the first mixed layer 270m has a refractive index close to 1.8. Since a ratio of the indium tin oxide (ITO) is higher than that of the aluminum zinc oxide (AZO) in the lower region of the first mixed layer 270m, the lower region of the first mixed layer 270m has a refractive index close to 1.6. Since ratios of the aluminum zinc oxide (AZO) and the indium tin oxide (ITO) are similar to each other in the intermediate region of the first mixed layer 270m, the intermediate region of the first mixed layer 270m has a refractive index of about 1.7.

In the first mixed layer 270m, ratios of the first material and the second material are gradually changed, such that a refractive index is gradually changed. In a region in which the refractive index is rapidly changed, interface reflection is generated. In the present exemplary embodiment, since the first mixed layer 270m in which the refractive index is gradually changed is present between the first layer 270a and the second layer 270b of the first electrode 270, it is possible to prevent the interface reflection from being generated.

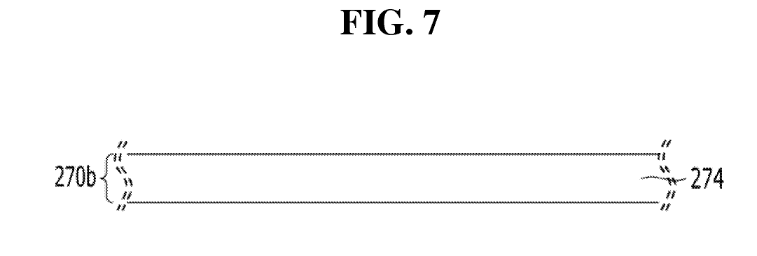

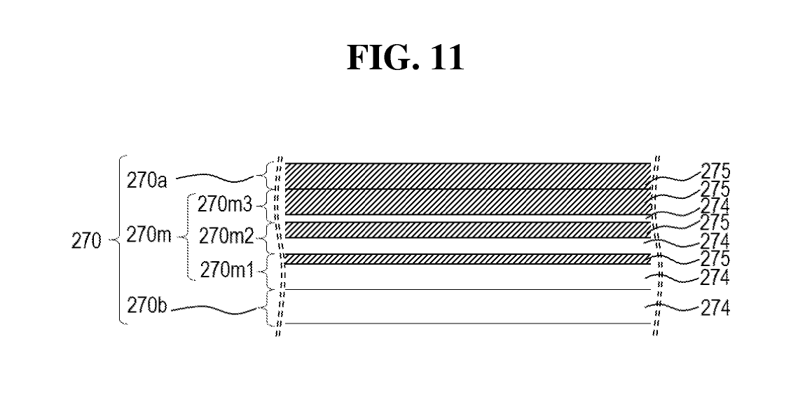

Next, a method of forming the first layer 270a, the first mixed layer 270m, and the second layer 270b of the first electrode 270 will be described with reference to FIGS. 7 and 11.

FIGS. 7 to 11 are process cross-sectional views showing a method of forming a first layer, a first mixed layer, and a second layer of the first electrode.

The first electrode may be formed by an atomic layer deposition (ALD) method or a plasma enhanced atomic layer deposition (PEALD) method.

The atomic layer deposition (ALD) method is a kind of thin film deposition method. First, a reactant A including a metal source of a thin film that is to be formed is injected onto and adsorbed on a surface of a substrate mounted in a reaction chamber for a predetermined time, and purge gas of nitrogen (N2), argon (Ar), helium (H), or the like, which is inert gas, is injected to remove the reactant A in a gas state that remains without reacting. Then, a reactant B is injected as reaction gas for exchange with the reactant A adsorbed on the substrate to induce an exchange reaction in the reactant A adsorbed on the substrate, thereby forming the thin film. One cycle of deposition process of forming one layer of thin film through the injection of the reactant A→the injection of the purge gas→the injection of the reactant B→the injection of the purge gas as described above is performed plural times, thereby forming a thin film having a desired thickness.

The plasma enhanced atomic layer deposition (PEALD) method is similar to the atomic layer deposition (ALD) method, and one cycle of deposition process configured of the injection of the reactant A→the injection of the purge gas→the injection of the reactant B→the injection of the purge gas is repeated in the plasma enhanced atomic layer deposition (PEALD) method. Here, plasma is generated at the time of injecting the reactant B or the reactant B is injected in a plasma state to form a thin film.

First, as shown in FIG. 7, the second layer 270b made of a second material 274 is formed. The second material 274 may be an indium tin oxide (ITO). The second material 274 is deposited by an atomic layer deposition method or a plasma enhanced atomic layer deposition method.

The second material 274 is deposited through one cycle configured of injection of cyclopentadienyl indium (InCp)→injection of purge gas→injection of ozone (O₃)→injection of purge gas→injection of tetrakis-dimethyl-amine tin (TDMASn)→injection of purge gas→injection of hydrogen peroxide (H₂O₂). A process of depositing the second material 274 is repeated plural times.

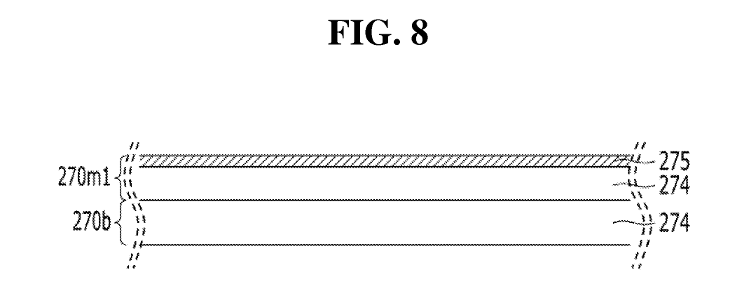

Then, as shown in FIG. 8, a lower region 270m1 of the first mixed layer 270m made of a mixture of the second material 274 and a first material 275 is formed on the second layer 270b made of the second material 274. The first material 275 may be an aluminum zinc oxide (AZO). The first material 275 and the second material 274 are deposited by an atomic layer deposition method or a plasma enhanced atomic layer deposition method.

The second material 274 is deposited through one cycle configured of injection of cyclopentadienyl indium (InCp)→injection of purge gas→injection of ozone (O₃)→injection of purge gas→injection of tetrakis-dimethyl-amine tin (TDMASn)→injection of purge gas→injection of hydrogen peroxide (H₂O₂).

The first material 275 is deposited through one cycle configured of injection of diethyzinc (DEZn)→injection of purge gas→injection of water vapor (H₂O)→injection of purge gas→injection of trimethylaluminum (TMAl)→injection of purge gas→injection of water vapor (H₂O)→injection of purge gas.

In the lower region 270m1 of the first mixed layer 270m, the repetition number of cycle of depositing the second material 274 is more than that of cycle of deposing the first material 275. For example, after the cycle of depositing the second material 274 is repeated about ten times, the cycle of depositing the first material 275 is performed about once. Therefore, in the lower region 270m1 of the first mixed layer 270m, a thin film thickness of the second material 274 is thicker than that of the first material 275.

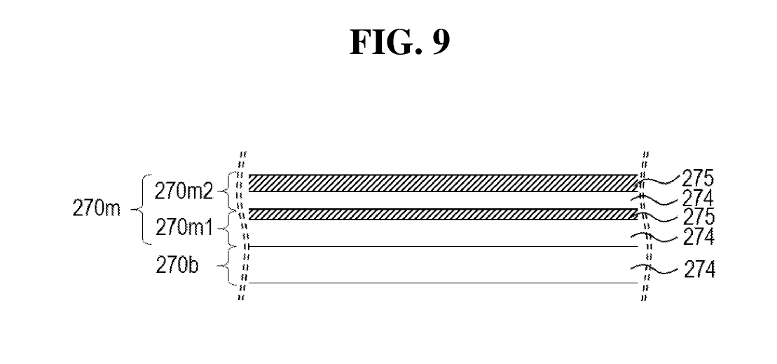

Then, as shown in FIG. 9, the cycle of depositing the second material 274 and the cycle of depositing the first material 275 are repeated, respectively, to form the first mixed layer 270m. Here, the repetition number of cycle of depositing the second material 274 is gradually decreased, and the repetition number of cycle of depositing the first material 275 is gradually increased.

In an intermediate region 270m2 of the first mixed layer 270m, the repetition number of cycle of depositing the second material 274 is similar to that of cycle of deposing the first material 275. For example, after the cycle of depositing the second material 274 is repeated about five times, the cycle of depositing the first material 275 is repeated about five times. Therefore, in the intermediate region 270m2 of the first mixed layer 270m, a thin film thickness of the second material 274 is similar to that of the first material 275.

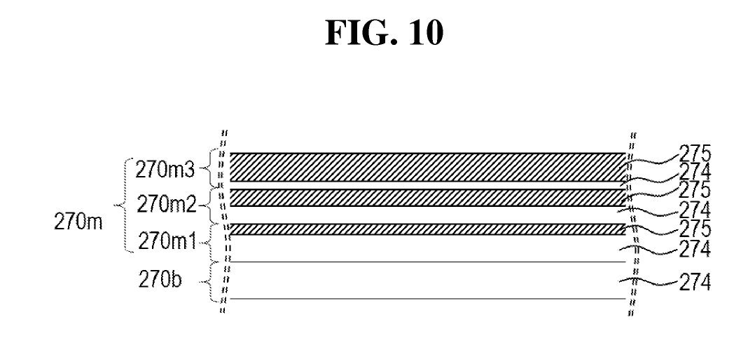

Then, as shown in FIG. 10, the cycle of depositing the second material 274 and the cycle of depositing the first material 275 are repeated, respectively, to form the first mixed layer 270m. Here, the repetition number of cycle of depositing the second material 274 is gradually decreased, and the repetition number of cycle of depositing the first material 275 is gradually increased.

In an upper region 270m3 of the first mixed layer 270m, the repetition number of cycle of depositing the second material 274 is less than that of cycle of deposing the first material 275. For example, after the cycle of depositing the second material 274 is performed about once, the cycle of depositing the first material 275 is performed about ten times. Therefore, in the upper region 270m3 of the first mixed layer 270m, a thin film thickness of the second material 274 is thinner than that of the first material 275.

Then, as shown in FIG. 11, the cycle of depositing the first material 275 is repeated to form the first layer 270a.

As described above, a layer made of only the second material, a layer made of only the first material, and a layer made of a mixture of the first and second materials may be formed using the atomic layer deposition method or the plasma enhanced atomic layer deposition method. In addition, in the layer made of the mixture of the first and second materials, thin film thicknesses of the first and second materials may be adjusted to adjust ratios of the first and second materials and allow the ratios of the first and second materials to be changed in the thickness direction.

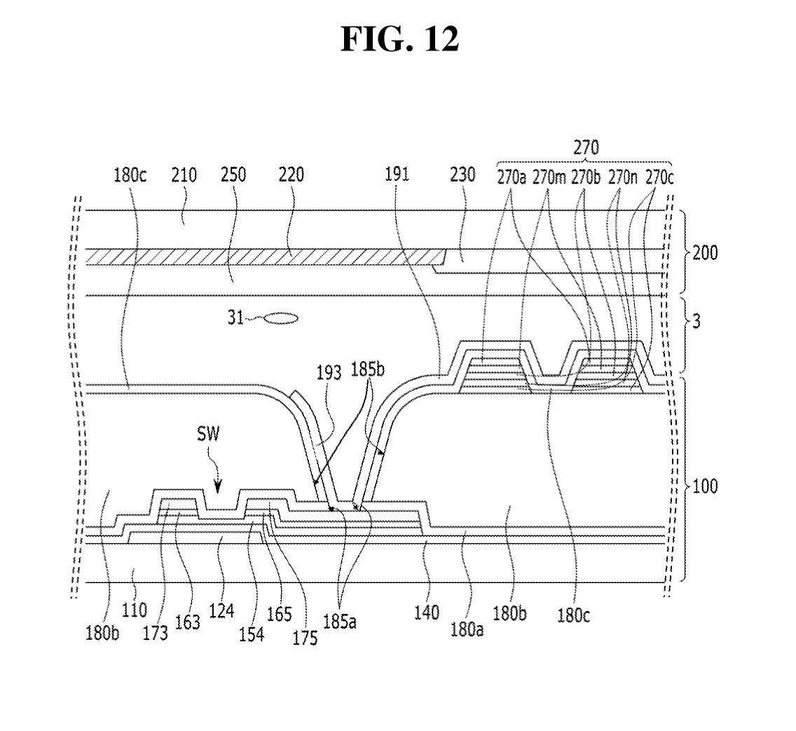

Next, the liquid crystal display device according to an exemplary embodiment of the present invention will be described with reference to FIG. 12.

Since the liquid crystal display device according to an exemplary embodiment of the present invention shown in FIG. 12 is substantially similar to the liquid crystal display device according to an exemplary embodiment of the present invention shown in FIG. 5, a description therefor will be omitted. The liquid crystal display device according to the present exemplary embodiment is partially different from the liquid crystal display device according to the previous exemplary embodiment in that a third layer is further positioned under a second layer of a first electrode and a mixed layer is further positioned between the second and third layers of a first electrode, which will be described in detail

FIG. 12 is a cross-sectional view of the liquid crystal display device according to an exemplary embodiment of the present invention.

Similar to the previous exemplary embodiment, the liquid crystal display device according to an exemplary embodiment of the present invention includes a lower display panel 100 and an upper display panel 200 facing each other, and a liquid crystal layer 3 interposed between the upper and lower display panels 100 and 200.

The lower display panel 100 includes gate lines 121 and data lines 171 positioned on a first insulation substrate 110 and thin film transistors connected to the gate lines 121 and the data lines 171. A first passivation layer 180a and a second passivation layer 180b are positioned on the gate lines 121, the data lines 171, and the thin film transistors. First electrodes 270 are positioned on the second passivation layer 180b, an interlayer insulating layer 180c is positioned on the first electrodes 270, and second electrodes 191 are positioned on the interlayer insulating layer 180c.

The first electrode 270 includes a first layer 270a, a second layer 270b positioned under the first layer 270a, and a third layer 270c positioned under the second layer 270b. In addition, the first electrode 27 further includes a first mixed layer 270m positioned between the first layer 270a and the second layer 270b and a second mixed layer 270n positioned between the second layer 270b and the third layer 270c.

The first layer 270a of the first electrode 270 may be an indium zinc oxide (IZO). The indium zinc oxide (IZO) is made of an indium oxide (In₂O₃) and a zinc oxide (ZnO). Here, it is preferable that a weight ratio of the indium oxide is 20 wt % or less. The first layer 270a of the first electrode 270 may also be made of a transparent metal oxide that does not contain the indium oxide (In₂O₃). For example, the first layer 270a of the first electrode 270 may be made of an aluminum zinc oxide (AZO) or a gallium zinc oxide (GZO). That is, it is preferable that the first layer 270a of the first electrode 270 does not contain the indium zinc oxide or contains a small amount of indium zinc oxide.

The second layer 270b of the first electrode 270 may be made of an indium zinc oxide (IZO) or an indium tin oxide (ITO). Here, a weight ratio of an indium oxide (In₂O₃) in the indium zinc oxide (IZO) or the indium tin oxide (ITO) may be 80 wt % or more. That is, the second layer 270b of the first electrode 270 may contain a large amount of indium-zinc oxide.

The third layer 270c of the first electrode 270 may be an indium zinc oxide (IZO). The indium zinc oxide (IZO) is made of an indium oxide (In₂O₃) and a zinc oxide (ZnO). Here, it is preferable that a weight ratio of the indium oxide is 20 wt % or less. The third layer 270c of the first electrode 270 may also be made of a transparent metal oxide that does not contain the indium oxide (In₂O₃). For example, the third layer 270c of the first electrode 270 may be made of an aluminum zinc oxide (AZO) or a gallium zinc oxide (GZO). That is, it is preferable that the third layer 270c of the first electrode 270 does not contain the indium zinc oxide or contains a small amount of indium zinc oxide.

The first mixed layer 270m of the first electrode 270 is made of a mixture of a first material configuring the first layer 270a and a second material configuring the second layer 270b. Here, ratios of the first material and the second material are changed in the thickness direction. The closer to the first layer 270a, the higher the ratio of the first material in the first mixed layer 270m, and the closer to the second layer 270b, the higher the ratio of the second material in the first mixed layer 270m. That is, a ratio of the first material is higher than that of the second material in an upper region of the first mixed layer 270m, a ratio of the second material is higher than that of the first material in a lower region of the first mixed layer 270m, and ratios of the first material and the second material are similar to each other in an intermediate region of the first mixed layer 270m.

The second mixed layer 270n of the first electrode 270 is made of a mixture of the second material configuring the second layer 270b and the first material configuring the third layer 273c. Here, ratios of the second material and the first material are changed in the thickness direction. The closer to the second layer 270b, the higher the ratio of the second material in the second mixed layer 270n, and the closer to the third layer 270c, the higher the ratio of the first material in the second mixed layer 270n. That is, a ratio of the second material is higher than that of the first material in an upper region of the second mixed layer 270n, a ratio of the first material is higher than that of the second material in a lower region of the second mixed layer 270n, and ratios of the first material and the second material are similar to each other in an intermediate region of the second mixed layer 270n.

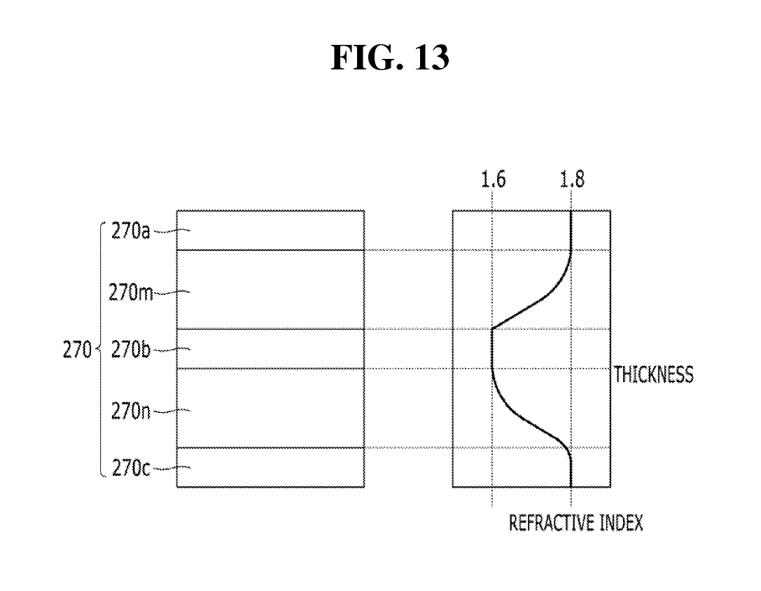

A change in a refractive index of the first electrode 270 depending on a mixed ratio of the first and second materials will be described below with reference to FIG. 13.

FIG. 13 is a view showing a change in a refractive index of a first electrode in a thickness direction in the liquid crystal display device according to an exemplary embodiment of the present invention.

The first layer 270a and the third layer 270c of the first electrode 270 may be made of the aluminum zinc oxide (AZO), and the second layer 270b thereof may be made of the indium tin oxide (ITO). Here, the first mixed layer 270m and the second mixed layer 270n may be made of a mixture of the aluminum zinc oxide (AZO) and the indium tin oxide (ITO).

Refractive indices of the first layer 270a and the third layer 270c made of the aluminum zinc oxide (AZO) are about 1.8, and a refractive index of the second layer 270b made of the indium tin oxide (ITO) is about 1.6. Refractive indices of the first mixed layer 270m and the second mixed layer 270n may be between about 1.6 and about 1.8. Since a ratio of the aluminum zinc oxide (AZO) is higher than that of the indium tin oxide (ITO) in the upper region of the first mixed layer 270m and the lower region of the second mixed layer 270n, the upper region of the first mixed layer 270m and the lower region of the second mixed layer 270n have a refractive index close to 1.8. Since a ratio of the indium tin oxide (ITO) is higher than that of the aluminum zinc oxide (AZO) in the lower region of the first mixed layer 270m and the upper region of the second mixed layer 270n, the lower region of the first mixed layer 270m and the upper region of the second mixed layer 270n have a refractive index close to 1.6. Since ratios of the aluminum zinc oxide (AZO) and the indium tin oxide (ITO) are similar to each other in the intermediate region of the first mixed layer 270m and the intermediate region of the second mixed layer 270n, the intermediate region of the first mixed layer 270m and the intermediate region of the second mixed layer 270n have a refractive index of about 1.7.

In the first mixed layer 270m and the second mixed layer 270n, ratios of the first and second materials are gradually changed, such that a refractive index is gradually changed. In a region in which the refractive index is rapidly changed, interface reflection is generated. In the present exemplary embodiment, since the first mixed layer 270m in which the refractive index is gradually changed is present between the first layer 270a and the second layer 270b of the first electrode 270 and the second mixed layer 270n in which the refractive index is gradually changed is present between the second layer 270b and the third layer 270c of the first electrode 270, it is possible to prevent the interface reflection from being generated

The first electrode 270 may be formed using an atomic layer deposition (ALD) method or a plasma enhanced atomic layer deposition (PEALD) method. The cycle of depositing the first material may be repeated to form a layer made of only the first material, and the cycle of depositing the second material may be repeated to form a layer made of only the second material. In addition, the cycle of depositing the first material and the cycle of depositing the second material may be repeated, respectively, to form a layer made of a mixture of the first material and the second material. Here, the repetition number of cycle of depositing the first material and the repetition number of cycle of depositing the second material are adjusted to adjust thin film thicknesses of the first material and the second material, thereby making it possible to adjust ratios of the first material and the second material. Therefore, the ratios of the first material and the second material may be changed in the thickness direction.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

### DESCRIPTION OF SYMBOLS

110: first insulation substrate
121: gate line
171: data line
180a: first passivation layer
180b: second passivation layer
180c: interlayer insulating layer
191: second electrode
210: second insulation substrate
270: first electrode
270a: first layer of first electrode
270b: second layer of first electrode
270c: third layer of first electrode
270m: first mixed layer of first electrode
270m1: lower region of first mixed layer
270m2: intermediate region of first mixed layer
270m3: upper region of first mixed layer
270n: second mixed layer of first electrode

What is claimed is:

1. A liquid crystal display device comprising:
a substrate;
a gate line and a data line positioned on the substrate;
a thin film transistor connected to the gate line and the data line;
a passivation layer positioned on the gate line, the data line, and the thin film transistor;
a first electrode positioned on the passivation layer;
an interlayer insulating layer positioned on the first electrode; and
a second electrode positioned on the interlayer insulating layer,
wherein the first electrode includes a first layer made of an indium-zinc oxide in which a weight ratio of an indium oxide is 20 wt % or less or made of a transparent metal oxide that does not contain an indium oxide.

2. The liquid crystal display device of claim 1, wherein the first layer is made of an aluminum zinc oxide or a gallium zinc oxide.

3. The liquid crystal display device of claim 1, wherein the interlayer insulating layer is made of a silicon oxide or a silicon nitride.

4. The liquid crystal display device of claim 3, wherein the passivation layer is made of an organic insulating material.

5. The liquid crystal display device of claim 1, wherein the first electrode further includes a second layer positioned under the first layer.

6. The liquid crystal display device of claim 5, wherein the first layer is made of an aluminum zinc oxide or a gallium zinc oxide.

7. The liquid crystal display device of claim 5, wherein the second layer is made of an indium zinc oxide or an indium tin oxide.

8. The liquid crystal display device of claim 5, wherein the first electrode further includes a third layer positioned under the second layer.

9. The liquid crystal display device of claim 8, wherein the third layer is made of an indium-zinc oxide in which a weight ratio of an indium oxide is 20 wt % or less or is made of a transparent metal oxide that does not contain an indium oxide.

10. The liquid crystal display device of claim 8, wherein the second layer is made of an indium zinc oxide or an indium tin oxide.

11. The liquid crystal display device of claim 5, wherein the first electrode further includes
a second layer positioned under the first layer; and
a first mixed layer positioned between the first layer and the second layer.

12. The liquid crystal display device of claim 11, wherein
the first layer is made of a first material,
the second layer is made of a second material, and
the first mixed layer is made of a mixture of the first material and the second material.

13. The liquid crystal display device of claim 12, wherein in the first mixed layer, ratios of the first material and the second material are changed in a thickness direction.

14. The liquid crystal display device of claim 13, wherein the closer to the first layer, the higher the ratio of the first material in the first mixed layer, and the closer to the second layer, the higher the ratio of the second material in the first mixed layer.

15. The liquid crystal display device of claim 12, wherein the first material is an aluminum zinc oxide or a gallium zinc oxide.

16. The liquid crystal display device of claim 12, wherein the second material is an indium zinc oxide or an indium tin oxide.

17. The liquid crystal display device of claim 11, wherein the first electrode is formed by an atomic layer deposition method or a plasma enhanced atomic layer deposition method.

18. The liquid crystal display device of claim 11, wherein the first electrode further includes
a third layer positioned under the second layer; and
a second mixed layer positioned between the second layer and the third layer.

19. The liquid crystal display device of claim 18, wherein
the first layer and the third layer are made of a first material,
the second layer is made of a second material, and
the first mixed layer and the second mixed layer are made of a mixture of the first material and the second material.

20. The liquid crystal display device of claim 19, wherein in the first mixed layer and the second mixed layer, ratios of the first material and the second material are changed in a thickness direction.

21. The liquid crystal display device of claim 20, wherein the closer to the first layer, the higher the ratio of the first material in the first mixed layer, and the closer to the second layer, the higher the ratio of the second material in the first mixed layer, and
the closer to the third layer, the higher the ratio of the first material in the second mixed layer, and the closer to the second layer, the higher the ratio of the second material in the second mixed layer.

22. The liquid crystal display device of claim 19, wherein the first material is an indium-zinc oxide in which a weight ratio of an indium oxide is 20 wt % or less or is a transparent metal oxide that does not contain an indium oxide.

23. The liquid crystal display device of claim 19, wherein the second material is an indium zinc oxide or an indium tin oxide.

24. The liquid crystal display device of claim 18, wherein the first electrode is formed by an atomic layer deposition method or a plasma enhanced atomic layer deposition method.

25. The liquid crystal display device of claim 1, wherein a predetermined voltage is applied to the first electrode.

26. The liquid crystal display device of claim 25, wherein the second electrode is connected to the thin film transistor.
